(19) United States
(12) Patent Application Publication
(10) Pub. No.: US 2025/0212478 A1
(43) Pub. Date: Jun. 26, 2025

(54) GROUP-III ELEMENT NITRIDE SEMICONDUCTOR SUBSTRATE AND BONDED SUBSTRATE

(71) Applicant: NGK INSULATORS, LTD., Nagoya-shi (JP)

(72) Inventors: Ayumi SAITO, Nagoya-shi (JP); Tomohiko SUGIYAMA, Nagoya-shi (JP)

(21) Appl. No.: 19/077,266

(22) Filed: Mar. 12, 2025

Related U.S. Application Data
(63) Continuation of application No. PCT/JP2023/016348, filed on Apr. 25, 2023.

(30) Foreign Application Priority Data
Oct. 6, 2022 (WO) PCT/JP2022/037460

(51) Int. Cl. H10D 62/85; C30B 29/40

(52) U.S. Cl. CPC H10D 62/8503; C30B 29/403

(57) ABSTRACT

A Group-III element nitride semiconductor substrate includes: a first surface; and a second surface. When “n” peak wavenumbers, which are obtained by measuring peak wavenumbers corresponding to an E₂^{H} phonon mode at intervals of 5 μm on a straight line from a position of a center of mass of the first surface to a position of a center of mass of the second surface in a range of from a site inward from the surface of the first surface by 5 μm to a site inward from the second surface by 5 μm, are represented by B1 to Bn from a side closer to the first surface where “n” represents the number of the measured peak wavenumbers, a difference (Bₘₐₓ−Bₘᵢₙ) between a maximum peak wavenumber Bₘₐₓ and a minimum peak wavenumber Bₘᵢₙ out of the “n” measured values is 2.0 cm⁻¹ or less.

### CROSS-REFERENCE TO RELATED APPLICATIONS

This application is a continuation under 35 U.S.C. 120 of International Application PCT/JP2023/016348 having the International Filing Date of 25 Apr. 2023 and having the benefit of the earlier International Application PCT/JP2022/037460 having the International Filing Date of 6 Oct. 2022. Each of the identified applications is fully incorporated herein by reference.

### BACKGROUND OF THE INVENTION

### 1. Field of the Invention

The present invention relates to a Group-III element nitride semiconductor substrate. More specifically, the present invention relates to a Group-III element nitride semiconductor substrate including a main surface and a back surface in a front and back relationship, the Group-III element nitride semiconductor substrate being suppressed in occurrence of a chipping failure at the time of device production.

### 2. Description of the Related Art

A Group-III element nitride semiconductor substrate, such as a gallium nitride (GaN) wafer, an aluminum nitride (AlN) wafer, or an indium nitride (InN) wafer, has been used as each of the substrates of various semiconductor devices (e.g., Patent Literature 1).

A semiconductor substrate includes a first surface and a second surface. When the first surface is defined as a main surface, and the second surface is defined as a back surface, the main surface is typically a Group-III element polar surface, and the back surface is typically a nitrogen polar surface. An epitaxial crystal may be grown on the main surface, and various devices may be produced thereon.

The Group-III element nitride semiconductor substrate has been used as a base substrate of a semiconductor device, such as an LED or an LD.

In a gallium nitride substrate, a failure, such as a crack, a fracture, or a chipping, is liable to occur at the time of device production. It has been known that such failure is more liable to occur as a difference in residual stress in the substrate becomes larger (Patent Literatures 2 to 4). A Raman analysis method is generally used as a method of evaluating a residual stress in such substrate, and the residual stress is evaluated by the wavenumber of a peak corresponding to an E₂^{H} phonon mode. It has been conceived that as a change in wavenumber becomes larger, a change in residual stress becomes larger.

In Patent Literature 2, there is a report of a gallium nitride substrate in which a difference between the maximum value and minimum value of a Raman shift corresponding to an E₂^{H} phonon mode in a region except a region distant inward from the peripheral edge of a surface having an area of 10 cm² or more by up to 5 mm is 0.5 cm⁻¹ or less.

In Patent Literature 3, there is a report of a gallium nitride substrate having a diameter of 150 mm or more in which a difference between the maximum value and minimum value of peak wavenumbers corresponding to an E₂^{H} phonon mode at a total of five places, that is, the center of its surface and four places on the peripheral edge thereof is 0.1 cm⁻¹ or more and 1 cm⁻¹ or less.

In Patent Literature 4, there is a report of a gallium nitride substrate having an area of 18 cm² or more in which a difference in Raman shift amount corresponding to an E₂^{H} phonon mode between the position of the center of mass of its front surface and the position of the center of mass of its back surface is 0.1 cm⁻¹ or more and 0.5 cm⁻¹ or less, and a difference in Raman shift amount between the position of the center of mass of the front surface and the peripheral edge thereof is 0.1 cm⁻¹ or more and 0.5 cm⁻¹ or less.

Meanwhile, a semiconductor device produced on a gallium nitride substrate is cut out together with the substrate after the production. There is a problem in that, when a chipping failure occurs in the gallium nitride substrate at the time of the cut-out, the yield of the device reduces.

### CITATION LIST

### Patent Literature

[PTL 1] JP 2005-263609 A
[PTL 2] JP 4386031 B2
[PTL 3] JP 6405767 B2
[PTL 4] JP 6384229 B2

### SUMMARY OF THE INVENTION

An object of the present invention is to provide a Group-III element nitride semiconductor substrate including a first surface and a second surface, the Group-III element nitride semiconductor substrate being suppressed in occurrence of a chipping failure at the time of device production.

[1] According to at least one embodiment of the present invention, there is provided a Group-III element nitride semiconductor substrate. The Group-III element nitride semiconductor substrate includes: a first surface; and a second surface. The Group-III element nitride semiconductor substrate has a thickness of 100 μm or more. When “n” peak wavenumbers, which are obtained by measuring peak wavenumbers corresponding to an E₂^{H} phonon mode at intervals of 5 μm on a straight line from a position of a center of mass of a surface of the first surface to a position of a center of mass of a surface of the second surface in a range of from a site inward from the surface of the first surface by 5 μm to a site corresponding to one half of the thickness of the substrate, and in a range of from a site inward from the surface of the second surface by 5 μm to the site corresponding to one half of the thickness of the substrate, are represented by B1 to Bn in the stated order from a side closer to the surface of the first surface where “n” represents the number of the measured peak wavenumbers, and represents an integer obtained by rounding up a digit after a decimal point of a value [(thickness (μm) of Group-III element nitride semiconductor substrate−5 (μm))/5 (μm)], a difference (Bₘₐₓ−Bₘᵢₙ) between a maximum peak wavenumber Bₘₐₓ and a minimum peak wavenumber Bₘᵢₙ out of the “n” measured values is 2.0 cm⁻¹ or less.

[2] In the above-mentioned item [1], the difference (Bₘₐₓ-Bₘᵢₙ) is 1.5 cm⁻¹ or less.

[3] In the above-mentioned item [2], the difference (Bₘₐₓ-Bₘᵢₙ) is 1.0 cm⁻¹ or less.

[4] In any one of the above-mentioned items [1] to [3], the “n” peak wavenumbers fluctuate so as to determine a mountain and valley-shaped fluctuation curve in a thickness direction of the substrate.

[5] In any one of the above-mentioned items [1] to [4], the Group-III element nitride semiconductor substrate has a diameter of 45 mm or more.

[6] In any one of the above-mentioned items [1] to [5], the thickness is 300 μm or more.

[7] According to another aspect of the present invention, there is provided a bonded substrate. The bonded substrate includes: the Group-III element nitride semiconductor substrate of any one of the above-mentioned items [1] to [6]; and a support substrate bonded thereto.

According to the embodiment of the present invention, the Group-III element nitride semiconductor substrate including a first surface and a second surface, the Group-III element nitride semiconductor substrate being suppressed in occurrence of a chipping failure at the time of device production, can be provided.

### BRIEF DESCRIPTION OF THE DRAWINGS

FIG. 1 is a typical schematic sectional view of a Group-III element nitride semiconductor substrate according to an embodiment of the present invention.

FIG. 2 is an optical micrograph of an end surface of a chip obtained in Example 3.

FIG. 3 is an optical micrograph of an end surface of a chip obtained in Comparative Example 1.

FIG. 4 is a conceptual graph diagram describing the fluctuation state of a peak wavenumber corresponding to an E₂^{H} phonon mode along the thickness direction of a substrate in the embodiment of the present invention.

FIG. 5 is a graph showing the fluctuation state of a peak wavenumber corresponding to an E₂^{H} phonon mode along the thickness direction of the substrate of Example 3.

FIG. 6 is a graph showing the fluctuation state of a peak wavenumber corresponding to an E₂^{H} phonon mode along the thickness direction of the substrate of Comparative Example 1.

### DESCRIPTION OF THE EMBODIMENTS

When the expression “weight” is used herein, the expression may be replaced with “mass” that is commonly used as an SI unit representing a weight.

A Group-III element nitride semiconductor substrate according to an embodiment of the present invention is typically a freestanding substrate formed of a Group-III element nitride crystal. In this description, the term “freestanding substrate” means a substrate that is not deformed or broken by its own weight at the time of its handling, and hence can be handled as a solid. The freestanding substrate may be used as each of the substrates of various semiconductor devices, such as a light-emitting device and a power-controlling device.

The Group-III element nitride semiconductor substrate according to the embodiment of the present invention typically has a wafer shape (substantially complete round shape). However, the substrate may be processed into any other shape such as a rectangular shape as required.

Any appropriate size may be adopted as the size (diameter) of the Group-III element nitride semiconductor substrate according to the embodiment of the present invention to the extent that an effect exhibited by the embodiment of the present invention is not impaired. Such size is, for example, 25 mm (about 1 inch), from 45 mm to 55 mm (about 2 inches), from 95 mm to 105 mm (about 4 inches), from 145 mm to 155 mm (about 6 inches), from 195 mm to 205 mm (about 8 inches), or from 295 mm to 305 mm (about 12 inches). The size (diameter) of the Group-III element nitride semiconductor substrate according to the embodiment of the present invention is preferably 45 mm or more, more preferably 50 mm or more.

The thickness of the Group-III element nitride semiconductor substrate according to the embodiment of the present invention (when the thickness is not constant, the thickness of a site having the largest thickness) is 100 μm or more, preferably from 300 μm to 1,000 μm.

Typical examples of the Group-III element nitride include gallium nitride (GaN), aluminum nitride (AlN), indium nitride (InN), and a mixed crystal thereof. Those nitrides may be used alone or in combination thereof.

The Group-III element nitride is specifically GaN, AlN, InN, GaₓAl₁₋ₓN (1>x>0), GaₓIn₁₋ₓN (1>x>0), AlₓIn₁₋ₓN (1>x>0), or GaₓAl_{y}In_{z}N (1>x>0, 1>y>0, x+y+z=1). Those nitrides may be doped with various n-type dopants or p-type dopants.

Typical examples of the p-type dopants include zinc (Zn), manganese (Mn), Iron (Fe), beryllium (Be), magnesium (Mg), strontium (Sr), and cadmium (Cd). Those dopants may be used alone or in combination thereof.

Typical examples of the n-type dopants include silicon (Si), germanium (Ge), tin (Sn), and oxygen (O). Those dopants may be used alone or in combination thereof.

The plane direction of the Group-III element nitride semiconductor substrate may be set to any one of a c-plane, an m-plane, an a-plane, and a specific crystal plane tilted from each of the c-plane, the a-plane, and the m-plane, and particularly when the plane direction is set to the c-plane, the effect exhibited by the embodiment of the present invention is expressed to a larger extent. Examples of the specific crystal plane tilted from each of the c-plane, the a-plane, and the m-plane may include so-called semipolar planes, such as a {11-22} plane and a {20-21} plane. In addition, the plane direction is permitted to include not only a so-called just plane vertical to the c-plane, the a-plane, the m-plane, or the specific crystal plane tilted from each of the planes but also an off-angle in the range of ±5°.

The Group-III element nitride semiconductor substrate according to the embodiment of the present invention is a Group-III element nitride semiconductor substrate including a first surface and a second surface. When the first surface is defined as a main surface, and the second surface is defined as a back surface, as long as the plane direction of the Group-III element nitride semiconductor substrate is the c-plane, the main surface is typically a Group-III element polar surface, and the back surface is typically a nitrogen polar surface. However, the main surface may be set to the nitrogen polar surface, and the back surface may be set to the Group-III element polar surface. An epitaxial crystal may be grown on the main surface, and various devices may be produced thereon. The back surface may be held with a susceptor or the like to transfer the Group-III element nitride semiconductor substrate according to the embodiment of the present invention.

In the description of the Group-III element nitride semiconductor substrate according to the embodiment of the present invention, the first surface is described as the main surface, and the second surface is described as the back surface. Accordingly, in this description, the term “main surface” may be replaced with “first surface,” the term “first surface” may be replaced with “main surface,” the term “back surface” may be replaced with “second surface,” and the term “second surface” may be replaced with “back surface.”

The main surface may be a mirror surface or a non-mirror surface. The main surface is preferably a mirror surface.

The main surface is preferably a surface from which an affected layer is substantially removed and which has a small surface roughness in a microscopic region from the viewpoint of obtaining such a semiconductor device that devices to be produced by epitaxially growing device layers have satisfactory characteristics and variations in device characteristics between the devices are reduced.

The back surface may be a mirror surface or a non-mirror surface.

The term “mirror surface” refers to a surface subjected to mirror processing, the surface being brought into a state in which the roughness and waviness of the surface are reduced to such an extent that light is reflected after the mirror processing, and hence the fact that an object is reflected on the surface subjected to the mirror processing can be visually observed. In other words, the term refers to a surface in a state in which the magnitude of each of the roughness and waviness of the surface after the mirror processing is reduced to such an extent as to be sufficiently negligible with respect to the wavelength of visible light. An epitaxial crystal can be sufficiently grown on the surface subjected to the mirror processing.

Any appropriate method may be adopted as a method for the mirror processing to the extent that the effect exhibited by the embodiment of the present invention is not impaired. An example of such method is a method including performing the mirror processing through use of one, or a combination of two or more, of the following apparatus: a polishing apparatus using a tape; a lapping apparatus using diamond abrasive grains; and a chemical mechanical polishing (CMP) apparatus using a slurry such as colloidal silica and a polishing pad made of a nonwoven fabric. When the affected layer remains on the surface after the processing, the affected layer is removed. As a method of removing the affected layer, there are given, for example, a method including removing the affected layer through use of reactive ion etching (RIE) or a chemical liquid, and a method including annealing the substrate.

The term “non-mirror surface” refers to a surface that is not subjected to mirror processing, and a typical example thereof is a rough surface obtained by surface-roughening treatment.

Any appropriate method may be adopted as a method for the surface-roughening treatment to the extent that the effect exhibited by the embodiment of the present invention is not impaired. Examples of such method include: grinding with abrasive stone; laser texture processing; etching treatment with various chemical liquids and gases; physical or chemical coating treatment; and texturing by machining.

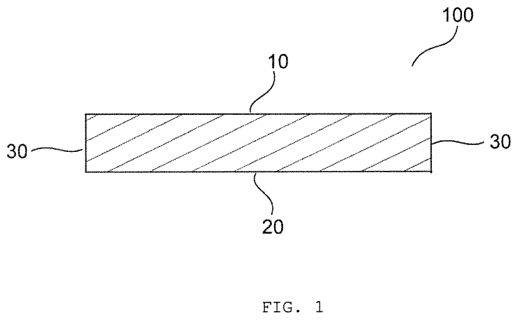

FIG. 1 is a typical schematic sectional view of the Group-III element nitride semiconductor substrate according to the embodiment of the present invention. As illustrated in FIG. 1, a Group-III element nitride semiconductor substrate 100 according to the embodiment of the present invention typically has a main surface (Group-III element polar surface) 10 and a back surface (nitrogen polar surface) 20. The Group-III element nitride semiconductor substrate 100 according to the embodiment of the present invention may have a side surface 30.

An end portion of the Group-III element nitride semiconductor substrate according to the embodiment of the present invention may adopt any appropriate form to the extent that the effect exhibited by the embodiment of the present invention is not impaired. Examples of the shape of the end portion of the Group-III element nitride semiconductor substrate according to the embodiment of the present invention include: a shape in which a main surface side and a back surface side are each chamfered so as to be a flat surface; a shape in which the main surface side and the back surface side are each chamfered in an R-shape; a shape in which only the main surface side of the end portion is chamfered so as to be a flat surface; and a shape in which only the back surface side of the end portion is chamfered so as to be a flat surface.

When the end portion of the Group-III element nitride semiconductor substrate according to the embodiment of the present invention is chamfered, the chamfered portion may be arranged over the one entire round of an outer peripheral portion, or may be arranged only in part of the outer peripheral portion.

In the Group-III element nitride semiconductor substrate according to the embodiment of the present invention, when “n” peak wavenumbers, which are obtained by measuring peak wavenumbers corresponding to an E₂^{H} phonon mode at intervals of 5 μm on a straight line from the position of the center of mass of the surface of the first surface to the position of the center of mass of the surface of the second surface in the range of from a site inward from the surface of the first surface by 5 μm to a site corresponding to one half of the thickness of the substrate, and in the range of from a site inward from the surface of the second surface by 5 μm to the site corresponding to one half of the thickness of the substrate, are represented by B1 to Bn in the stated order from a side closer to the surface of the first surface where “n” represents the number of the measured peak wavenumbers, and represents an integer obtained by rounding up a digit after the decimal point of a value [(thickness (μm) of Group-III element nitride semiconductor substrate−5 (μm))/5 (μm)], a difference (Bₘₐₓ−Bₘᵢₙ) between the maximum peak wavenumber Bₘₐₓ and the minimum peak wavenumber Bₘᵢₙ out of the “n” measured values is 2.0 cm⁻¹ or less, preferably 1.5 cm⁻¹ or less, more preferably 1.0 cm⁻¹ or less. When the above-mentioned difference (Bₘₐₓ−Bₘᵢₙ) falls within the above-mentioned ranges, there can be provided a Group-III element nitride semiconductor substrate suppressed in occurrence of a chipping failure at the time of device production.

The above-mentioned “n” represents the number of the measured peak wavenumbers.

For example, when the thickness of the Group-III element nitride semiconductor substrate is 300 μm (when the thickness is a multiple of 5 μm), “n” represents 59. The measurement is performed at the following measurement places: the measurement is performed at the site inward from the surface of the first surface by 5 μm (whose peak wavenumber is B1), a site inward from the surface of the first surface by 10 μm (whose peak wavenumber is B2), and a site inward from the surface of the first surface by 15 μm (whose peak wavenumber is B3); and then, the measurement place is shifted inward in increments of 5 μm, and the measurement is continued up to the site corresponding to one half of the thickness of the substrate (site inward from the surface of the first surface by 150 μm) (whose peak wavenumber is B30). Next, the measurement is performed at the following measurement places: the measurement is performed at the site inward from the surface of the second surface by 5 μm (whose peak wavenumber is B59), a site inward from the surface of the second surface by 10 μm (whose peak wavenumber is B58), and a site inward from the surface of the second surface by 15 μm (whose peak wavenumber is B57); and then, the measurement place is shifted inward in increments of 5 μm, and the site corresponding to one half of the thickness of the substrate (site inward from the surface of the second surface by 150 μm) overlaps the site inward from the surface of the first surface by 150 μm, that is, its peak wavenumber is B30.

For example, when the thickness of the Group-III element nitride semiconductor substrate is 302 μm (when the thickness is not a multiple of 5 μm), “n” represents 60. The measurement is performed at the following measurement places: the measurement is performed at the site inward from the surface of the first surface by 5 μm (whose peak wavenumber is B1), a site inward from the surface of the first surface by 10 μm (whose peak wavenumber is B2), and a site inward from the surface of the first surface by 15 μm (whose peak wavenumber is B3); and then, the measurement place is shifted inward in increments of 5 μm, and the measurement is continued up to a site inward from the surface of the first surface by 150 μm (whose peak wavenumber is B30), the site being closest to the site corresponding to one half of the thickness of the substrate (site inward from the surface of the first surface by 151 μm). Next, the measurement is performed at the following measurement places: the measurement is performed at the site inward from the surface of the second surface by 5 μm (whose peak wavenumber is B60), a site inward from the surface of the second surface by 10 μm (whose peak wavenumber is B59), and a site inward from the surface of the second surface by 15 μm (whose peak wavenumber is B58); and then, the measurement place is shifted inward in increments of 5 μm, and the measurement is continued up to a site inward from the surface of the second surface by 150 μm (whose peak wavenumber is B31), the site being closest to the site corresponding to one half of the thickness of the substrate (site inward from the surface of the second surface by 151 μm). A distance between the site inward from the surface of the first surface by 150 μm (whose peak wavenumber is B30) and the site inward from the surface of the second surface by 150 μm (whose peak wavenumber is B31) is 2 μm.

The inventors of the present invention have made extensive investigations with a view to solving the following problem of the related art: when a chipping failure occurs in a Group-III element nitride semiconductor substrate at the time of the cut-out of a semiconductor device produced on the Group-III element nitride semiconductor substrate together with the substrate, the yield of the device reduces. As a result, the inventors have found the following: in a Group-III element nitride semiconductor substrate including a first surface and a second surface, when “n” peak wavenumbers, which are obtained by measuring peak wavenumbers corresponding to an E₂^{H} phonon mode at intervals of 5 μm on a straight line from the position of the center of mass of the surface of the first surface to the position of the center of mass of the surface of the second surface in the range of from a site inward from the surface of the first surface by 5 μm to a site corresponding to one half of the thickness of the substrate, and in the range of from a site inward from the surface of the second surface by 5 μm to the site corresponding to one half of the thickness of the substrate, are represented by B1 to Bn in the stated order from a side closer to the surface of the first surface where “n” represents the number of the measured peak wavenumbers, and represents an integer obtained by rounding up a digit after the decimal point of a value [(thickness (μm) of Group-III element nitride semiconductor substrate−5 (μm))/5 (μm)], a difference (Bₘₐₓ−Bₘᵢₙ) between the maximum peak wavenumber Bₘₐₓ and the minimum peak wavenumber Bₘᵢₙ out of the “n” measured values is related to the size of a chipping occurring at the time of the cutting of the Group-III element nitride semiconductor substrate. In consideration of the fact that a chipping having a large size serves as a chipping failure, the inventors have reached the following technical idea: when the Group-III element nitride semiconductor substrate is designed by using the above-mentioned difference (Bₘₐₓ−Bₘᵢₙ) as an evaluation criterion, there can be provided a Group-III element nitride semiconductor substrate suppressed in occurrence of a chipping failure at the time of device production. Thus, the inventors have completed the present invention.

When a wurtzite gallium nitride (GaN) crystal is taken as an example, the term “E₂^{H} phonon mode” as used herein refers to, for example, a mode in which N atoms adjacent to each other in the GaN crystal vibrate in an in-plane direction in its C-plane. A Raman shift corresponding to the E₂^{H} phonon mode is identified by a wavenumber at the highest peak of peaks corresponding to the E₂^{H} phonon mode in a Raman shift spectrum obtained by Raman analysis. Here, in each of the above-mentioned Patent Literatures 2 to 4, there is a description that the wavenumber of the E₂^{H} phonon mode of the wurtzite GaN crystal at a temperature of 300 K is 567.6 cm⁻¹, and a wavenumber at the highest peak of peaks corresponding to the E₂^{H} phonon mode appears near 567.6 cm⁻¹.

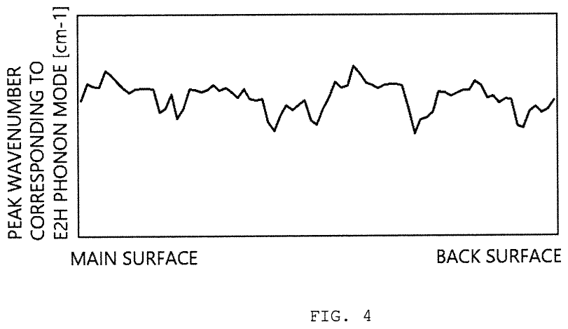

The above-mentioned “n” peak wavenumbers may typically fluctuate so as to determine a mountain and valley-shaped (uneven shaped) fluctuation curve in the thickness direction of the substrate. For example, the above-mentioned peak wavenumbers may fluctuate in accordance with such a fluctuation curve as shown in FIG. 4 from the main surface of the substrate toward the back surface thereof. According to the embodiment of the present invention, when the difference (Bₘₐₓ−Bₘᵢₙ) between the maximum peak wavenumber Bₘₐₓ and the minimum peak wavenumber Bₘᵢₙ, that is, a difference between the highest mountain and the deepest valley in the fluctuation curve is controlled to a predetermined value or less, the occurrence of a chipping failure at the time of device production can be suppressed. One feature of the embodiment of the present invention lies in that not an average fluctuation degree (the average of deviations from a central value) in the fluctuation curve but the difference between the highest mountain and the deepest valley is controlled. A deviation from the central value in a stress (peak wavenumber) in the thickness direction represents the size of the local strain of a crystal lattice. When the strain is large, such a state that a crack is present at an atomic level is established. It may be assumed that a chipping occurs via the following mechanism: a force concentrates on the crack at an atomic level at the time of cut-out processing to extend the crack into a crack at a macroscopic level. Accordingly, it may be assumed that the chipping failure can be suppressed by controlling not the average fluctuation degree but the difference between the highest mountain and the deepest valley by which a local stress fluctuation can be evaluated. However, such mechanism is merely an assumption, and hence the embodiment of the present invention is not construed in a limited manner and the embodiment of the present invention is not bound by the mechanism.

The Group-III element nitride semiconductor substrate according to the embodiment of the present invention may be produced by any appropriate method to the extent that the effect exhibited by the embodiment of the present invention is not impaired. A method of producing the Group-III element nitride semiconductor substrate according to the embodiment of the present invention, which is preferred because the effect exhibited by the embodiment of the present invention is expressed to a larger extent, is described below.

The Group-III element nitride semiconductor substrate according to the embodiment of the present invention is typically produced as described below. A seed crystal film is formed on the main surface of a base substrate, and a Group-III element nitride layer is formed on the Group-III element polar surface of the seed crystal film. Next, a Group-III element nitride layer (seed crystal film+Group-III element nitride layer) serving as a freestanding substrate is separated from the base substrate. Thus, a freestanding substrate having a main surface and a back surface is obtained.

Any appropriate material may be adopted as a material for the base substrate to the extent that the effect exhibited by the embodiment of the present invention is not impaired. Examples of such material include sapphire, crystal oriented alumina, gallium oxide, AlₓGa₁₋ₓN (0≤x≤1), GaAs, and SiC.

Any appropriate material may be adopted as a material for the seed crystal film to the extent that the effect exhibited by the embodiment of the present invention is not impaired. Examples of such material include AlₓGa₁₋ₓN (0≤x≤1) and InₓGa₁₋ₓN (0≤x≤1). Of those, gallium nitride is preferred.

Any appropriate formation method may be adopted as a method of forming the seed crystal film to the extent that the effect exhibited by the embodiment of the present invention is not impaired. Such formation method is, for example, a vapor growth method, and preferred examples thereof include a metal-organic chemical vapor deposition (MOCVD) method, a hydride vapor phase epitaxy (HVPE) method, a pulsed excitation deposition (PXD) method, a molecular beam epitaxy (MBE) method, and a sublimation method. Of those, a metal-organic chemical vapor deposition (MOCVD) method is more preferred as the method of forming the seed crystal film.

The formation of the seed crystal film by the MOCVD method is preferably performed by, for example, depositing a low-temperature grown buffer layer by from 20 nm to 50 nm at from 450° C. to 550° C., and then depositing a film having a thickness of from 2 μm to 4 μm at from 1,000° C. to 1, 200° C.

Any appropriate growth direction may be adopted as the growth direction of the Group-III element nitride crystal layer to the extent that the effect exhibited by the embodiment of the present invention is not impaired. Examples of such growth direction include: the normal direction of the c-plane of a wurtzite structure; the normal direction of each of the a-plane and m-plane thereof; and the normal direction of a plane tilted from each of the c-plane, the a-plane, and the m-plane.

Any appropriate formation method may be adopted as a method of forming the Group-III element nitride crystal layer to the extent that the effect exhibited by the embodiment of the present invention is not impaired as long as a layer to be formed by the method has a crystal direction substantially following the crystal direction of the seed crystal film. Examples of such formation method include: gas phase growth methods, such as a metal-organic chemical vapor deposition (MOCVD) method, a hydride vapor phase epitaxy (HVPE) method, a pulsed excitation deposition (PXD) method, a MBE method, and a sublimation method; liquid phase growth methods, such as a Na flux method, an ammonothermal method, a hydrothermal method, and a sol-gel method; a powder growth method utilizing solid phase growth of powder; and a combination thereof.

When the Na flux method is adopted as the method of forming the Group-III element nitride crystal layer, the Na flux method is preferably performed in conformity with a production method described in JP 5244628 B2 by appropriately adjusting the conditions and the like so that the effect exhibited by the embodiment of the present invention can be expressed to a larger extent.

The formation of the Group-III element nitride crystal layer by the Na flux method is typically preferably performed as follows: a seed crystal substrate (base substrate+seed crystal film) is arranged in a crucible serving as a growing container under a nitrogen atmosphere; a melt composition containing a Group-III element, metal sodium (Na), and as required, a dopant (e.g., an n-type dopant, such as germanium (Ge), silicon (Si), or oxygen (O); or a p-type dopant, such as beryllium (Be), magnesium (Mg), calcium (Ca), strontium (Sr), zinc (Zn), or cadmium (Cd)) is further loaded into the crucible; the crucible is lidded; the lidded crucible is loaded into an external container; the external container is further loaded into a pressure-resistant container; and under a nitrogen atmosphere, after the temperature and pressure of the container are increased, the container is rotated while the temperature and the pressure are retained.

The above-mentioned temperature increase is performed until the temperature of the content preferably reaches the range of from 700° C. to 1,000° C., and more preferably reaches the range of from 800° C. to 900° C. In this description, the reaching temperature may be referred to as “final reaching temperature.”

The time of the above-mentioned temperature increase is preferably 105 minutes or more, more preferably from 120 minutes to 250 minutes, still more preferably from 140 minutes to 220 minutes, particularly preferably from 160 minutes to 200 minutes. When the time of the above-mentioned temperature increase is so short as to deviate from the above-mentioned ranges, the timing of the start of the growth of the crystal or the growth rate thereof may vary. As a result, regions having different residual stresses are liable to be formed, and hence a chipping failure may occur at the time of the cut-out of a semiconductor device produced on the Group-III element nitride semiconductor substrate to be obtained together with the substrate.

In the above-mentioned temperature increase, a temperature increase time required for the temperature to reach 400° C. is preferably 5 minutes or more, more preferably from 10 minutes to 70 minutes, still more preferably from 20 minutes to 60 minutes, particularly preferably from 30 minutes to 50 minutes.

In the above-mentioned temperature increase, a temperature increase time required for the temperature to reach the final reaching temperature from 400° C. is preferably 100 minutes or more, more preferably from 110 minutes to 210 minutes, still more preferably from 120 minutes to 200 minutes, still more preferably from 130 minutes to 190 minutes, particularly preferably from 140 minutes to 180 minutes, most preferably from 150 minutes to 170 minutes. When the above-mentioned temperature increase time required for the temperature to reach the final reaching temperature from 400° C. deviates from the above-mentioned ranges, the timing of the start of the growth of the crystal or the growth rate thereof may vary. As a result, regions having different residual stresses are liable to be formed, and hence a chipping failure may occur at the time of the cut-out of a semiconductor device produced on the Group-III element nitride semiconductor substrate to be obtained together with the substrate.

The above-mentioned pressure increase is performed preferably in the range of from 1 MPa to 7 MPa, more preferably in the range of from 2 MPa to 6 MPa.

Next, the Group-III element nitride crystal layer is separated from the base substrate, so that the freestanding substrate including the Group-III element nitride crystal layer may be obtained.

Any appropriate method may be adopted as a method of separating the Group-III element nitride crystal layer from the base substrate to the extent that the effect exhibited by the embodiment of the present invention is not impaired. Examples of such method include: a method including causing the Group-III element nitride crystal layer to spontaneously separate from the base substrate through use of a thermal shrinkage difference in a temperature decrease step after the growth of the Group-III element nitride crystal layer; a method including separating the Group-III element nitride crystal layer from the base substrate through chemical etching; a method including separating the Group-III element nitride crystal layer from the base substrate by a laser lift-off method including applying laser light from the back surface side of the base substrate; and a method including separating the Group-III element nitride crystal layer from the base substrate through grinding. In addition, the freestanding substrate including the Group-III element nitride crystal layer may be obtained by slicing the Group-III element nitride crystal layer through utilization of a wire saw or the like.

In the Group-III element nitride crystal layer thus obtained by the Na flux method, it is preferred that a plate surface thereof be flattened by being ground with abrasive stone or the like, and the plate surface be then smoothened, for example, by being lapped with diamond abrasive grains.

Next, the freestanding substrate is shaped into a circular shape having a desired diameter by grinding its outer peripheral portion.

Any appropriate size may be adopted as the size of the freestanding substrate to the extent that the effect exhibited by the embodiment of the present invention is not impaired. Such size is, for example, 25 mm (about 1 inch), from 45 mm to 55 mm (about 2 inches), from 95 mm to 105 mm (about 4 inches), from 145 mm to 155 mm (about 6 inches), from 195 mm to 205 mm (about 8 inches), or from 295 mm to 305 mm (about 12 inches).

Next, the main surface and/or the back surface is subjected to removal processing by, for example, grinding, lapping, or polishing so that the semiconductor substrate is turned into a thin plate having a desired thickness, followed by flattening. Thus, a freestanding substrate is obtained.

At the time of the performance of surface processing, such as grinding, lapping, or polishing, the freestanding substrate is typically bonded to a processing surface plate by, for example, using a wax. At this time, the pressure at which the freestanding substrate is bonded to the processing surface plate, specifically, a pressure to be applied to the freestanding substrate when the freestanding substrate is bonded to the processing surface plate is appropriately adjusted.

The thickness of the freestanding substrate after the polishing (when the thickness is not constant, the thickness of a place having the largest thickness) is preferably from 300 μm to 1,000 μm.

The outer peripheral edge of the freestanding substrate is chamfered through grinding as required. When an affected layer remains on the surface of the main surface of the substrate, the affected layer is substantially removed. In addition, when a residual stress resulting from the affected layer remains on the surface of the back surface thereof, the residual stress is removed. Thus, the Group-III element nitride semiconductor substrate according to the embodiment of the present invention is finally obtained.

In the Group-III element nitride semiconductor substrate according to the embodiment of the present invention, the chamfering may be performed by any appropriate chamfering method to the extent that the effect exhibited by the embodiment of the present invention is not impaired. Examples of such chamfering method include: grinding with a diamond abrasive stone; polishing with a tape; and chemical mechanical polishing (CMP) using a slurry such as colloidal silica and a polishing pad made of a nonwoven fabric.

A crystal can be epitaxially grown on the main surface (Group-III element polar surface) of the Group-III element nitride semiconductor substrate to be obtained, and the formation of a functional layer can provide a functional device.

The epitaxial crystal to be grown on the Group-III element nitride semiconductor substrate to be obtained may be, for example, gallium nitride, aluminum nitride, indium nitride, or a mixed crystal thereof. Specific examples of such epitaxial crystal include GaN, AlN, InN, GaₓAl₁₋ₓN (1>x>0), GaₓIn₁₋ₓN (1>x>0), AlₓIn₁₋ₓN (1>x>0), and GaₓAl_{y}In_{z}N (1>x>0, 1>y>0, x+y+z=1). In addition, examples of the functional layer to be arranged on the Group-III element nitride semiconductor substrate to be obtained include a rectifying device layer, a switching device, and a power semiconductor layer in addition to a light-emitting layer. In addition, the thickness and thickness distribution of the freestanding substrate may be reduced by subjecting the nitrogen polar surface to processing, such as grinding or polishing, after the arrangement of the functional layer on the Group-III element polar surface of the Group-III element nitride semiconductor substrate to be obtained.

A bonded substrate according to an embodiment of the present invention may be obtained by bonding the Group-III element nitride semiconductor substrate to be obtained and a support substrate to each other. That is, the bonded substrate according to the embodiment of the present invention includes the Group-III element nitride semiconductor substrate according to the embodiment of the present invention and the support substrate bonded thereto.

The bonded substrate according to the embodiment of the present invention may further include any appropriate layer to the extent that the effect exhibited by the embodiment of the present invention is not impaired. The kinds, functions, number, combination, arrangement, and the like of such layers may be appropriately determined in accordance with purposes.

Any appropriate thickness may be adopted as the thickness of the support substrate to the extent that the effect exhibited by the embodiment of the present invention is not impaired. The thickness of the support substrate is, for example, from 100 μm to 1,000 μm.

Any appropriate substrate may be used as the support substrate to the extent that the effect exhibited by the embodiment of the present invention is not impaired. The support substrate may include a monocrystalline body, or may include a polycrystalline body.

In the bonded substrate according to the embodiment of the present invention, for example, the bonding surface of the Group-III element nitride semiconductor substrate and the bonding surface of the support substrate are directly bonded to each other. Specifically, the bonded substrate according to the embodiment of the present invention is obtained, for example, as follows: the bonding surface of the support substrate and the bonding surface of the Group-III element nitride semiconductor substrate are caused to face each other; and the bonding surface of the support substrate and the bonding surface of the Group-III element nitride semiconductor substrate are subjected to surface activation, and are then bonded to each other. After that, a desired epitaxial film may be formed on the film formation surface of the Group-III element nitride semiconductor substrate.

In the bonded substrate according to the embodiment of the present invention, for example, a bonding layer may be arranged between the Group-III element nitride semiconductor substrate and the support substrate. Specifically, the bonded substrate according to the embodiment of the present invention is obtained, for example, as follows: the bonding surface of the bonding layer on the main surface of the support substrate and the bonding surface of the Group-III element nitride semiconductor substrate are caused to face each other; and the bonding surface of the bonding layer and the bonding surface of the Group-III element nitride semiconductor substrate are subjected to surface activation, and are then bonded to each other. After that, a desired epitaxial film may be formed on the film formation surface of the Group-III element nitride semiconductor substrate. The following may be performed: the bonding layer is arranged on the main surface of the Group-III element nitride semiconductor substrate, and the bonding surface of the bonding layer is directly bonded to the bonding surface of the support substrate. Alternatively, the following may be performed: a first bonding layer is arranged on the main surface of the Group-III element nitride semiconductor substrate, a second bonding layer is arranged on the main surface of the support substrate, and the bonding surface of the first bonding layer is directly bonded to the bonding surface of the second bonding layer.

When the bonded substrate according to the embodiment of the present invention is an embodiment in which the bonding layer is arranged between the Group-III element nitride semiconductor substrate and the support substrate, the bonding layer is preferably at least one kind selected from the group consisting of: tantalum pentoxide; alumina; aluminum nitride; silicon carbide; sialon; and Si₍₁₋ₓ₎ Oₓ (0.008≤x≤0.408). Thus, a bonding strength between the support substrate and the Group-III element nitride semiconductor substrate can be further improved.

Sialon is a ceramic obtained by sintering a mixture of silicon nitride and alumina, and has the following composition.

Si_{6-z}Al_{z}O_{z}N_{8-z}

That is, sialon has such composition that alumina is mixed in silicon nitride, and “z” represents the mixing ratio of alumina. “z” more preferably represents 0.5 or more. “z” more preferably represents 4.0 or less.

### EXAMPLES

The present invention is specifically described below by way of Examples. However, the present invention is by no means limited to Examples. Test and evaluation methods in Examples and the like are as described below. The term “part(s)” in the following description means “part(s) by weight” unless otherwise specified, and the term “%” in the following description means “wt %” unless otherwise specified.

### <Raman Analysis>

### (Measurement Conditions)

Apparatus: A microscopic laser Raman spectroscopy apparatus LabRam ARAMIS (manufactured by Horiba, Ltd.)
Light source: A semiconductor-excited solid laser (520 nm)
Spectrometer slit: 100 μm
Laser spot diameter: Φ0.8 μm
Objective lens: ×100
Detector: CCD (1,024×256 pixels)
Diffraction grating: 2,400 gr/mm

### (Correction Condition)

The peak of a Ne lamp at 1, 708 cm⁻¹ was used for wavenumber calibration. The peaks of a GaN substrate corresponding to an E₂^{H} phonon mode were approximated with a Gauss-Lorentz function, and then, a wavenumber at the highest peak was calculated.

### (Measurement Method)

A Ga surface at the position of the center of mass of the GaN substrate was irradiated with laser light, and the position at which the intensity of reflected light became maximum was defined as the outermost surface on a Ga surface side. A stage was moved upward therefrom by 5 μm to obtain a Raman spectrum. After that, the Raman spectrum was obtained while the stage was lifted in increments of 5 μm. The measurement was suspended at the time point when the height of the lifted stage reached one half of the thickness of the GaN substrate. The GaN substrate was inverted, and a N surface at the position of the center of mass of the substrate was irradiated with the laser light. The position at which the intensity of reflected light became maximum was defined as the outermost surface on a N surface side. As in the case where the measurement was started from the Ga surface side, while the stage was lifted, a spectrum was obtained in increments of 5 μm up to a height corresponding to one half of the thickness of the sample. When the Ga surface and/or N surface of the GaN substrate is roughened, the roughened surface is preferably polished before the measurement from a side closer to the roughened surface, and is more preferably polished so that its arithmetic average roughness Ra may be 1.0 nm or less. In addition, even when no polishing is performed, the arithmetic average roughness Ra of the surface to be subjected to the measurement is preferably 1.0 nm or less.

<Measurement of Difference Between Maximum Value and Minimum Value of Raman Shifts Corresponding to E₂^{H} Phonon Mode>

On the basis of peak wavenumbers corresponding to the E₂^{H} phonon mode obtained by the Raman analysis,
(1) “n” peak wavenumbers, which were obtained by measuring peak wavenumbers corresponding to the E₂^{H} phonon mode at intervals of 5 μm on a straight line from the position of the center of mass of the outermost surface on the Ga surface side to the position of the center of mass of the outermost surface on the N surface side in the range of from a site inward from the outermost surface on the Ga surface side by 5 μm to a site corresponding to one half of the thickness of the GaN substrate, and in the range of from a site inward from the outermost surface on the N surface side by 5 μm to the site corresponding to one half of the thickness of the GaN substrate, were represented by B1 to Bn in the stated order from a side closer to the outermost surface on the Ga surface side where “n” represented the number of the measured peak wavenumbers, and represented an integer obtained by rounding up a digit after the decimal point of a value [(thickness (μm) of Group-III element nitride semiconductor substrate−5 (μm))/5 (μm)], and
(2) a difference (Bₘₐₓ−Bₘᵢₙ) between the maximum peak wavenumber Bₘₐₓ and the minimum peak wavenumber Bₘᵢₙ out of the “n” measured values was determined.

### <Evaluation of Number of Chipping Failures at Time of Substrate Cutting>

The resultant GaN substrate was cut into a 10-millimeter square chip, and an end portion of the chip was observed with an optical microscope.

A chipping having a size in an inward direction of 100 μm or more out of chippings observed in the end portion was counted as a chipping failure.

The term “size in an inward direction” as used herein refers to a size calculated as described below. First, an image of the entire region of the end portion of the chip was taken with an optical microscope at a magnification of 50. In each of the resultant N images, two places of the end portion where no chipping occurred were connected to each other with a line, and the line was defined as a normal edge position. For each chipping, a line segment was drawn from an edge position formed by the chipping to the normal edge position so as to be the shortest distance. The length of the line segment was defined as the “size in an inward direction.”

### Example 1

A gallium nitride film having a thickness of 2 μm was formed on a sapphire substrate by an MOCVD method. Thus, a seed crystal substrate was produced. The seed crystal substrate was arranged in an alumina crucible in a glove box under a nitrogen atmosphere. Next, metal gallium (Ga) and metal sodium (Na) were loaded into the crucible so that the following ratio was obtained: Ga/(Ga+Na) (mol %)=15 mol %. The crucible was lidded with an alumina plate. The crucible was loaded into an internal container made of stainless steel, and was further loaded into an external container made of stainless steel capable of housing the internal container. The external container was closed with a container lid. The external container was arranged on a rotating table placed on a heating portion in a crystal production apparatus, and a pressure-resistant container storing the external container was lidded and sealed.

Next, the inside of the pressure-resistant container was evacuated to 0.1 Pa or less with a vacuum pump. Subsequently, an upper-stage heater, a middle-stage heater, and a lower-stage heater were adjusted to perform heating so that a heated space had a temperature of 870° C. The temperature was increased to 400° C. over 60 minutes, and was increased to 870° C. over 120 minutes. The container was retained under the state for 40 hours. At the time of the heating, a nitrogen gas was introduced into the container from a nitrogen gas cylinder until the pressure therein reached 4.0 MPa, and the external container was rotated about its center axis at a speed of 20 rpm in clockwise motion and counterclockwise motion with a constant period. After that, the container was naturally cooled to room temperature and reduced in pressure to an atmospheric pressure. After that, the lid of the pressure-resistant container was opened, and the crucible was taken out of the container. Solidified metal sodium in the crucible was removed, and a gallium nitride crystal grown on the seed crystal substrate was taken out.

The gallium nitride crystal thus obtained was separated from the seed substrate, and was polished and ground to produce the freestanding substrate of the gallium nitride crystal having a diameter of 50.8 mm and a thickness of 400 μm.

The Raman analysis of the produced freestanding substrate was performed, and a difference between the maximum value and minimum value of the Raman shifts thereof corresponding to an E₂^{H} phonon mode was measured. As a result, the difference was 1.70 cm⁻¹.

Nine chips were cut out of the freestanding substrate after the measurement, and an end portion of each of the chips was observed with an optical microscope. The observation was performed at a magnification of 50, and a chipping having a size in an inward direction of 100 μm or more was counted as a chipping failure. No chipping failure occurred.

### Example 2

The freestanding substrate of a gallium nitride crystal was produced in the same manner as in Example 1. However, in the crystal growth process, the temperature increase up to 400° C. was performed over 40 minutes, and the temperature increase from 400° C. to 870° C. was performed over 140 minutes.

The Raman analysis of the substrate was performed in the same manner as in Example 1, and a difference between the maximum value and minimum value of the Raman shifts thereof corresponding to an E₂^{H} phonon mode was measured. As a result, the difference was 1.48 cm⁻¹.

Nine chips were cut out of the freestanding substrate after the measurement, and an end portion of each of the chips was observed with an optical microscope. The observation was performed at a magnification of 50, and a chipping having a size in an inward direction of 100 μm or more was counted as a chipping failure. No chipping failure occurred.

### Example 3

The freestanding substrate of a gallium nitride crystal was produced in the same manner as in Example 1. However, in the crystal growth process, the temperature increase up to 400° C. was performed over 40 minutes, and the temperature increase from 400° C. to 870° C. was performed over 160 minutes.

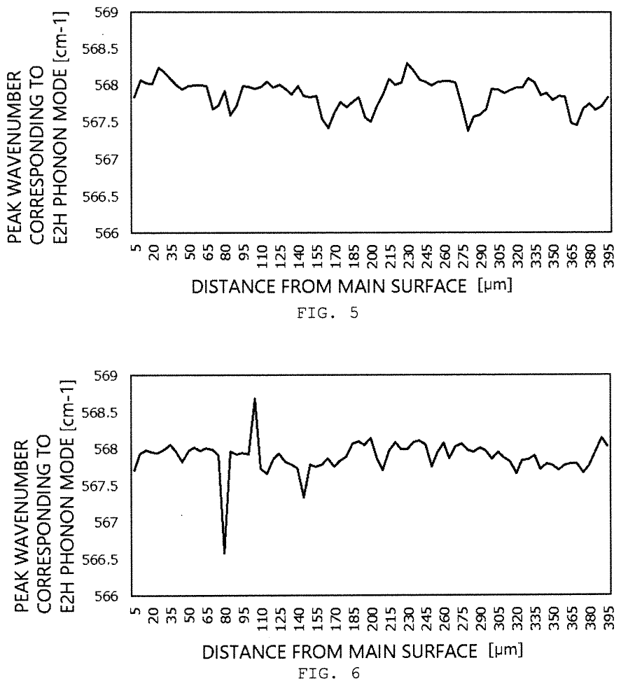

The Raman analysis of the substrate was performed in the same manner as in Example 1, and a difference between the maximum value and minimum value of the Raman shifts thereof corresponding to an E₂^{H} phonon mode was measured. As a result, the difference was 0.93 cm⁻¹. Further, the fluctuation state of the Raman shifts from the main surface of the substrate to the back surface thereof is shown in FIG. 5. In addition, the average fluctuation width Dave of the Raman shifts (peak wavenumbers) was calculated from FIG. 5. The Dave was 0.17. The Dave is the average value of the absolute values of differences between the average value of the B1 to the Bn and the respective peak wavenumbers.

Nine chips were cut out of the freestanding substrate after the measurement, and an end portion of each of the chips was observed with an optical microscope. The observation was performed at a magnification of 50, and a chipping having a size in an inward direction of 100 μm or more was counted as a chipping failure. No chipping failure occurred.

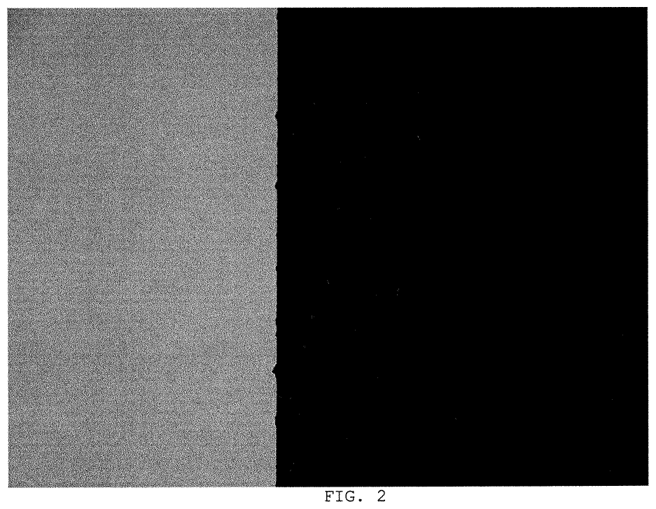

In addition, an optical micrograph of the end portion is shown in FIG. 2.

### Comparative Example 1

The freestanding substrate of a gallium nitride crystal was produced in the same manner as in Example 1. However, in the crystal growth process, the temperature increase up to 400° C. was performed over 40 minutes, and the temperature increase from 400° C. to 870° C. was performed over 60 minutes.

The Raman analysis of the substrate was performed in the same manner as in Example 1, and a difference between the maximum value and minimum value of the Raman shifts thereof corresponding to an E₂^{H} phonon mode was measured. As a result, the difference was 2.01 cm⁻¹. Further, the fluctuation state of the Raman shifts from the main surface of the substrate to the back surface thereof is shown in FIG. 6. In addition, the Dave was calculated from FIG. 6. The Dave was 0.14.

Nine chips were cut out of the freestanding substrate after the measurement, and an end portion of each of the chips was observed with an optical microscope. The observation was performed at a magnification of 50, and a chipping having a size in an inward direction of 100 μm or more was counted as a chipping failure. The chipping failures occurred in four chips out of the nine chips, and the total number of places where the failures occurred was 10.

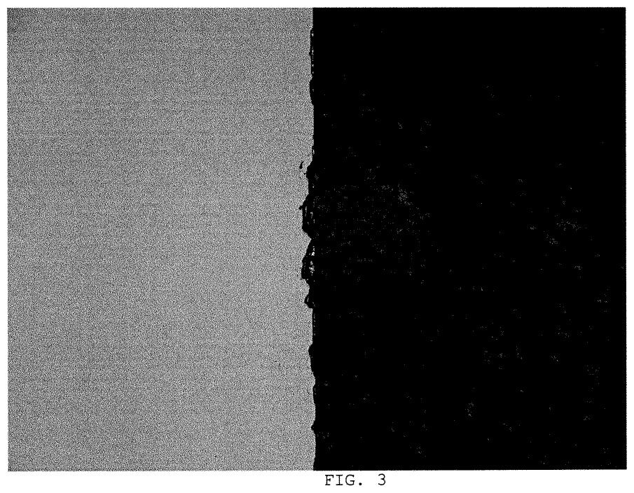

An optical micrograph of the end portion in which the chipping failure occurs is shown in FIG. 3.

### [Evaluation]

As is apparent from Examples and Comparative Example, it is found that the chipping failure can be suppressed by controlling the difference between the maximum value and minimum value of the Raman shifts (peak wavenumbers) corresponding to the E₂^{H} phonon mode to a predetermined value or less. Further, as is apparent from comparison between Example 3 and Comparative Example 1, it is found that even when the average fluctuation width Dave of the peak wavenumbers is small, in the case where the difference between the maximum value and minimum value of the peak wavenumbers is large, a chipping-suppressing effect is not obtained.

The Group-III element nitride semiconductor substrate according to the embodiment of the present invention may be utilized as each of the substrates of various semiconductor devices.

What is claimed is:

1. A Group-III element nitride semiconductor substrate, comprising:
a first surface; and
a second surface,
wherein the Group-III element nitride semiconductor substrate has a thickness of 100 μm or more, and
wherein when “n” peak wavenumbers, which are obtained by measuring peak wavenumbers corresponding to an E₂^{H} phonon mode at intervals of 5 μm on a straight line from a position of a center of mass of a surface of the first surface to a position of a center of mass of a surface of the second surface in a range of from a site inward from the surface of the first surface by 5 μm to a site corresponding to one half of the thickness of the substrate, and in a range of from a site inward from the surface of the second surface by 5 μm to the site corresponding to one half of the thickness of the substrate, are represented by B1 to Bn in the stated order from a side closer to the surface of the first surface where “n” represents the number of the measured peak wavenumbers, and represents an integer obtained by rounding up a digit after a decimal point of a value [(thickness (μm) of Group-III element nitride semiconductor substrate−5 (μm))/5 (μm)],
a difference (Bₘₐₓ−Bₘᵢₙ) between a maximum peak wavenumber Bₘₐₓ and a minimum peak wavenumber Bₘᵢₙ out of the “n” measured values is 2.0 cm⁻¹ or less.

2. The Group-III element nitride semiconductor substrate according to claim 1, wherein the difference (Bₘₐₓ−Bₘᵢₙ) is 1.5 cm⁻¹ or less.

3. The Group-III element nitride semiconductor substrate according to claim 2, wherein the difference (Bₘₐₓ−Bₘᵢₙ) is 1.0 cm⁻¹ or less.

4. The Group-III element nitride semiconductor substrate according to claim 1, wherein the “n” peak wavenumbers fluctuate so as to determine a mountain and valley-shaped fluctuation curve in a thickness direction of the substrate.

5. The Group-III element nitride semiconductor substrate according to claim 1, wherein the Group-III element nitride semiconductor substrate has a diameter of 45 mm or more.

6. The Group-III element nitride semiconductor substrate according to claim 1, wherein the thickness is 300 μm or more.

7. A bonded substrate, comprising:
the Group-III element nitride semiconductor substrate of claim 1; and
a support substrate bonded thereto.

8. A Group-III element nitride semiconductor substrate, comprising:
a first surface; and
a second surface,
wherein the Group-III element nitride semiconductor substrate has a thickness of from 300 μm to 1,000 μm,
wherein when “n” peak wavenumbers, which are obtained by measuring peak wavenumbers corresponding to an E₂^{H} phonon mode at intervals of 5 μm on a straight line from a position of a center of mass of a surface of the first surface to a position of a center of mass of a surface of the second surface in a range of from a site inward from the surface of the first surface by 5 μm to a site corresponding to one half of the thickness of the substrate, and in a range of from a site inward from the surface of the second surface by 5 μm to the site corresponding to one half of the thickness of the substrate, are represented by B1 to Bn in the stated order from a side closer to the surface of the first surface where “n” represents the number of the measured peak wavenumbers, and represents an integer obtained by rounding up a digit after a decimal point of a value [(thickness (μm) of Group-III element nitride semiconductor substrate−5 (μm))/5 (μm)],
a difference (Bₘₐₓ−Bₘᵢₙ) between a maximum peak wavenumber Bₘₐₓ and a minimum peak wavenumber Bₘᵢₙ out of the “n” measured values is 1.0 cm⁻¹ or less, and
wherein the “n” peak wavenumbers fluctuate so as to determine a mountain and valley-shaped fluctuation curve in a thickness direction of the substrate.

9. A bonded substrate, comprising:
the Group-III element nitride semiconductor substrate of claim 8; and
a support substrate bonded thereto.
